(19) United States
(12) Patent Application Publication
(10) Pub. No.: US 2018/0149972 A1
(43) Pub. Date: May 31, 2018

(54) HIGHLY RESOLVED PHOTOCHEMISTRY BELOW THE DIFFRACTION LIMIT BY MEANS OF SWITCHABLE PHOTO-ENOLIZATION

(71) Applicant: KARLSRUHER INSTITUT FUER TECHNOLOGIE, Karlsruhe (DE)

(72) Inventors: Joachim FISCHER, Kappelrodeck-Waldulm (DE); Benjamin RICHTER, Karlsruhe (DE); Alexander QUICK, Heiligkreuzsteinach (DE); Jonathan MUELLER, Stuttgart (DE); Martin BASTMEYER, Karlsruhe-Durlach (DE); Christopher BARNER-KOWOLLIK, Stutensee (DE); Martin WEGENER, Karlsruhe (DE)

(21) Appl. No.: 15/576,348

(22) PCT Filed: May 23, 2016
(86) PCT No.: PCT/EP2016/061523

§ 371 Date: Nov. 22, 2017

(30) Foreign Application Priority Data
May 27, 2015 (DE) 10 2015 108 358.2

(51) Int. Cl. G03F 7/004; G03F 7/20

(52) U.S. Cl. CPC G03F 7/0045; G03F 7/2053

(57) ABSTRACT

Disclosed is a method of conducting chemical reactions below the diffraction limit. The method comprises providing a composition comprising or consisting of at least one photoenol, initiating a reaction which emanates from the photoenol at a selected site by irradiation with light of a first, photoenol-activating wavelength, and concurrently or thereafter, suppressing the reaction emanating from the photoenol in the immediate vicinity of the selected site by irradiation with light of a second, photoenol-deactivating wavelength which creates an interference pattern having an intensity minimum or zero intensity at the selected site.

Documents cited in the present application are all incorporated in the present disclosure in their entirety by reference.

The present invention relates to a method of conducting photochemical reactions, for example optical lithographies, below the diffraction limit and to the use for that purpose of compositions comprising certain photoenols.

### RELATED ART

Photochemical reactions are very important in industry and find numerous applications. A large number of chemical reactions in photochemistry are induced by irradiation with light having a certain wavelength. These types of reaction include for example the photo-polymerization reaction started by photoinduced formation of free radicals or acids (“photo-polymerization”), the photoinduced removal of protective groups from certain molecules (“photo-uncaging”), the photoinduced release of certain molecules (“photorelease”) and also the photoinduced decoration of surfaces or porous bulk materials with functional molecules (“photofunctionalization”), for example by photoinduced Diels-Alder reactions.

The use of light as stimulus is simple, efficient and very selective. Focusing light into a small region or creating a spatially varying pattern of light, moreover, is capable of selectively inducing the reaction in certain spatial regions. However, there is a disadvantage with the use of light in that light cannot be focused into arbitrarily small areas and/or that extended patterns of light cannot have arbitrarily small spatial structures/periods. The so-called diffraction limit makes it impossible to produce light patterns having structure sizes significantly below half a wavelength of the light. Correspondingly, it is generally not possible to limit photoinduced reactions to length scales smaller than half a wavelength.

Yet there are many industrial and research sectors where photoinduced reactions limited to smaller regions would be very desirable. Examples are photoresists for lithography in the semiconductor industry, highly resolved surficial functionalization in biomedical engineering or photorelease of test substances limited to small volumes within the organelles of a living cell (research in cell biology).

Possible ways of how these limitations may be overcome are for example described in DE 10 2010 000 169, which also discloses methods of optical lithography below the diffraction limit which are based on specific photo-initiators with regard to their underlying chemistry.

A photosensitive substance such as, for example, a photoresist consists, in general, of at least one substance to be crosslinked (a monomer for example) and a photoactive molecule (a photoinitiator for example) to absorb light and start the crosslinking reaction.

Photoenols and reactions of this type are known from A. S. Quick et al., Adv. Funct. Mater. 2014, 1-10 and J. C. Netto-Ferreira et al., J. Am. Chem. Soc. 1991, 113, 5800-5803.

DE 10 325 459 A1 describes a generic concept for overcoming the diffraction limit by means of two-colored illumination and the use of switchable molecules. However, only very few materials systems and methods are known for putting this concept into practice. Existing methods are very restricted both as regards achievable resolution and as regards the diversity of their possible uses.

So there continues to be a substantial need for methods and systems to practice chemical reactions, especially optical lithographies, below the optical diffraction limit.

### Problem

The problem addressed by the present invention was that of providing a method for conducting photochemical reactions, especially for optical lithography, below the diffraction limit, and also resists and chemical systems suitable therefor.

The problem addressed by the present invention was further that of finding novel uses for photoenols.

The problem addressed by the present invention was not least also that of finding systems that are simpler and more flexible than the related art.

### Solution

This problem is solved by a method of conducting photochemical reactions, for example optical lithographies, below the diffraction limit, for example using photorelease, photouncaging or Diels-Alder reaction which method comprises
a) providing a composition containing or consisting of
   (i) at least one photoenol,
   (ii) optionally at least one reaction partner,
   (iii) optionally a solvent or solvent mixture,
   (iv) optionally further auxiliary substances,
b) initiating the reaction which emanates from the photoenol at a selected site by irradiation with light, preferably a laser, of a first, photoenol-activating, wavelength, and concurrently or thereafter
c) suppressing the reaction emanating from the photoenol in the immediate vicinity of the selected site by irradiation with light, preferably a laser, of a second, photoenol-deactivating wavelength,
   wherein
   the deactivation light radiated creates an interference pattern having an intensity minimum or zero intensity at the selected site.

The problem is also solved by a method of conducting photochemical reactions, for example optical lithographies, below the optical diffraction limit, wherein
a) a lacquer containing or consisting of
   (i) at least one photoenol,
   (ii) at least one dienophile,
   (iii) optionally a solvent or solvent mixture,
   (iv) optionally further auxiliary substances, is applied to a substrate,
b) the reaction of photoenol and dienophile(s) is initiated at a selected site by irradiation with light, preferably a laser, of a first, photoenol-activating wavelength, and concurrently or thereafter
c) the reaction of photoenol and dienophile(s) is suppressed in the immediate vicinity of the selected site by irradiation with light, preferably a laser, of a second, photoenol-deactivating wavelength,
   wherein
   the deexcitation light radiated creates an interference pattern having an intensity minimum or zero intensity at the selected site.

The problem is further solved by the use of photoenols for photochemical reactions, including in the afore-mentioned method and in a method for reducing the lithographic scale, and also in a lithographic lacquer based on photoenols and dienophiles.

The problem is further solved by a method for optical lithography below the diffraction limit, wherein
a) an optical molding is provided on the basis of a photoenol-dienophile system,
b) the reaction of photoenol and dienophile(s) is initiated at a selected site by irradiation with light, preferably a laser, of a first, photoenol-activating wavelength, and concurrently or thereafter
c) the reaction of photoenol and dienophile(s) is suppressed in the immediate vicinity of the selected site by irradiation with light, preferably a laser, of a second, photoenol-deactivating wavelength,
   wherein
   the deexcitation light radiated creates an interference pattern having an intensity minimum or zero intensity at the selected site.

### Terminological Definitions

Amounts indicated in the context of the present invention are all by weight, unless otherwise indicated.

The term “room temperature” is to be understood in the context of the present invention as meaning a temperature of 20° C. Reported temperatures are in degrees Celsius (° C.), unless otherwise indicated.

Unless otherwise indicated, the recited reactions and/or process steps are carried out at standard/atmospheric pressure, i.e., at 1013 mbar.

The term “lithography” in the context of the present invention comprehends, according to context, lithographic processes or lithographically created structures.

In the context of the present invention, the terms “lacquer” and “photoresist” are to be understood as meaning coating compositions in which radiating with light is capable of crosslinking regions fully or at least comparatively highly and hence of altering the refractive index of the regions and/or effecting a crosslinking/curing reaction.

In the context of the present invention, the term “molding” describes a photosensitive substance or a photosensitive mixture of substances whose solubility and/or etching resistance is alterable by irradiating with light. This can be for example a noncrosslinked polymer which is crosslinked, and thus rendered insoluble, by irradiating it with light. Alternatively, the step of irradiating with light can alter other properties of the molding, for example the refractive index.

In the context of the present invention, the term “substrate” is to be understood in the context of a surface functionalization as describing a surface or a (solvent pervious) body that provides photoenols, so the photoreaction described is capable of immobilizing the reaction partner on and/or in the substrate.

### DETAILED DESCRIPTION

The invention enables the starting of photochemical reactions on very small spatial scales. This enables for example a highly resolved two-dimensional or three-dimensional lithographic structurization of surfaces or volumes and also a precise spatially highly resolved chemical functionalization of surfaces or volumes. In conventional photochemical procedures, the so-called diffraction limit is a limit to the resolution attainable, whereas with the present invention there is no fundamental limit to the resolution and in principle a resolution down to molecular level is conceivable.

The present invention encompasses a novel chemical implementation which is employable specifically (but not exclusively) for lithography and precise chemical functionalization. In the present invention, certain molecules, so-called photoenols, form the basis for the switchable chemical system. Photoenols comprise molecules (ortho-alkylbenzaldehydes and -ketones) which form reactive intermediates (alpha-hydroxy-ortho-quino-dimethanes) on absorption of light. These intermediates constitute inter alia very efficient dienes for Diels-Alder reactions. Photoenols are typically excited in the near UV region by wavelengths of around 350 nm (first wavelength). The nature of the chemical process makes it possible for example to attach a large number of different chemical groups to the photoreactive components. (The intermediate o-quinodimethane formed may act inter alia as a reactive diene for Diels-Alder reactions (click reaction)). The present invention makes it possible to obtain photoresists for two-dimensional and three-dimensional structurization. The photoenols and the photochemical systems of the present invention are further suitable in the context of the present invention for fixing molecules to surfaces in a precise and locationally resolved manner. The photoenol chemistry in the context of the present invention further enables the realization of novel light-sensitive protecting groups and the light-induced release of substances. The applications of the chemical mechanism in combination with the highly resolving procedure of structurization are thus very diverse.

As mentioned, photoenols are molecules which, after excitation with light, transiently form a reactive species by photoenolization. The precise process from the excitation with light to the formation of the species involves several intermediate steps. The enol produced has proportions of two different molecular conformations (E/Z conformation). The E conformation is generally long lived for unsubstituted enols obtained, whereas the Z conformation is very short lived. The latter returns rapidly and spontaneously, via hydrogen reversion, back into the ground state of the starting molecule and can thus be re-excited at a later stage of the reaction.

In general, the photoenols which are useful in the context of the present invention and their reaction in the context of the present invention can be represented as follows:

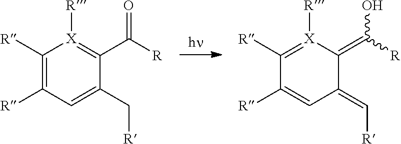

where the variables have the following meanings independently of one another:
R=H, alkyl, preferably methyl, aryl, preferably phenyl, halogenated alkyl, preferably CH₂ClCH₃,
R′=H, alkyl, preferably methyl,
R″=H, alkyl, preferably methyl, alkoxy, preferably methoxy, alkoxy moieties wherein the alkyl moiety bears yet additional functional groups, preferably hydroxyl, carboxylic acid,
R′″=H, hydroxyl, alkyl, preferably methyl, alkoxy, preferably methoxy, alkoxy moieties where the alkyl moiety bears yet additional functional groups, preferably hydroxyl, carboxylic acid, ester, polyethylene glycol, silane,
X=C, N,
   with the proviso that when X=N, R′″ is absent.

For photoenols to be useful in the context of the present invention it is essential that they comprise phenylmethanal derivatives/phenyl ketone derivatives which additionally have to have an ortho-positioned substituent that has a hydrogen atom in the alpha position.

Preferred photoenols for the purposes of the present invention are especially those selected from the group consisting of ortho-alkylbenzaldehyde and -ketones, and mixtures thereof.

In one version of the present invention, the photoenol is selected from the group consisting of alpha-chloro-2′,5′-dimethylacetophenone, 2′,4′-dimethylacetophenone, 2′,5′-dimethylacetophenone, alpha-chloro-2′,4′,6′-trimethylacetophenone, 2′-methylacetophenone, 6,6′-((2,2-bis((2-formyl-3-methylphenoxy)methyl)propane-1,3-diyl)bis(oxy))bis(2-methylbenzaldehyde), 2-hydroxy-6-methylbenzaldehyde, 2-methoxy-6-methylbenzaldehyde, 2-chloro-1-(2,5-dimethylphenyl)propan-1-one, 1-(2,5-dimethylphenyl)propan-1-one and mixtures thereof.

Useful dienophiles for the purposes of the present invention include in principle any compounds having a pi bond.

Preference is given to using compounds which have an electron-withdrawing group conjugated with an olefinic double bond and which are stable to the employed wavelengths of excitation and de-excitation light.

Useful dienophiles for the purposes of the present invention are more preferably selected from the group consisting of maleimides, maleic anhydride, maleic di- and monoesters, fumaric di- and monoesters, alkynes, acrylates, methacrylates, dithioesters, trithiocarbonates, propenals, butenals, fullerenes, dicyanoethene, tetracyanoethene, acetylenedicarboxylic mono- and diesters, but-2-en-4-olides, their derivatives and mixtures thereof.

It is similarly possible to employ the dienophiles as reactive groups attached to polymers; it is thus possible for example to coat surfaces with corresponding polymers and then to react the photoenols with the suitable attached dienophilic functional groups. That is, the term “dienophile” in one version of the present invention comprehends such polymer attached dienophilic functional groups.

One example thereof is poly[(methyl methacrylate)-co-(2-(2,5-dioxo-2,5-dihydro-1H-pyrrol-1-yl)ethyl methacrylate)].

It is likewise possible in one version of the present invention to utilize dienophilic groups that are incorporated in polymers, a general example of which comprises unsaturated polyesters wherein the C═C double bonds present in the polymer backbone can act as dienophilic groups. It is self-evidently also possible to choose other polymers, for example poly(meth)acrylates, which additionally bear appropriate groups.

Useful solvents for the purposes of the present invention include any solvents in which the photoenols and the dienophiles dissolve. However, it is advantageous and therefore preferable for the purposes of the present invention for the solvents to be non-protic.

Examples of useful solvents are methanol, gamma-butyrolactone (GBL), dichloromethane, chloroform, acetone, acetonitrile, tetrahydrofuran, ethyl acetate, dimethylformamide, acetophenone and also mixtures thereof.

In one version of the present invention, the solvents are selected from the group consisting of gamma-butyrolactone (GBL), acetophenone or mixtures thereof.

Auxiliary substances used in the context of the present invention are particularly those which do not interact with the light of the incident wavelengths. It is further advantageous for them not to enter any competing reactions with the functional groups of the photoenol and the dienophile.

In one version of the present invention auxiliary substances used are substances customary in the art and known in the art, preferably surface-active substances, flow control agents, pigments, fillers, crosslinkers, stabilizers, photoprotectants (with adapted wavelength profile).

One version of the present invention employs the photoenol and the dienophile in a molar ratio ranging from 1.5:1 to 1:1.5, preferably from 1.3:1 to 1:1.3 and especially from 1.1:1 to 1:1.1.

The reaction scheme which follows illustrates the reaction pathway and switching mechanism using the example of a light-induced Diels-Alder addition via photoenolization:

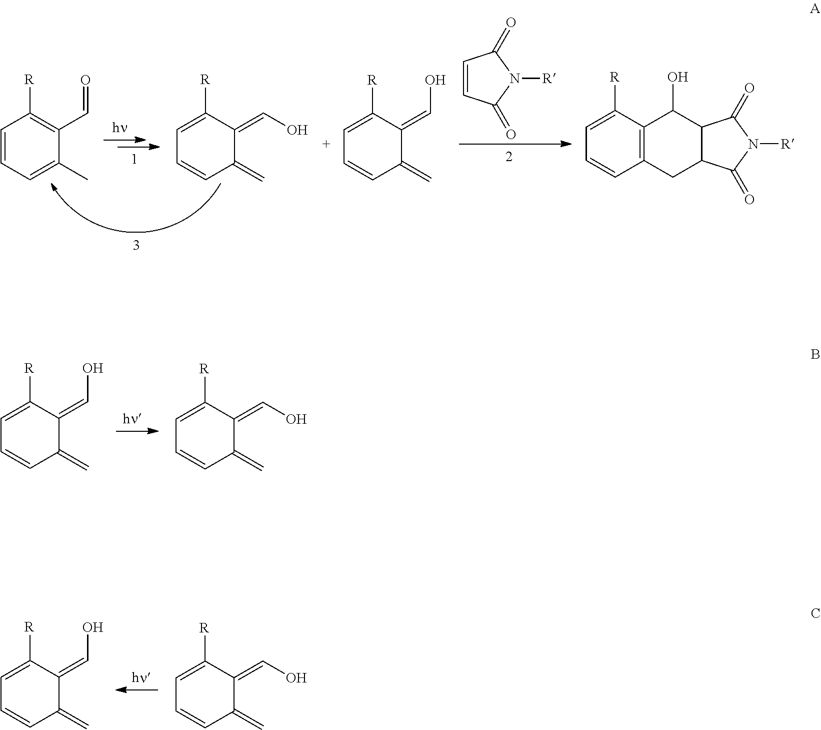

A) Schematic depiction of photoenolization (1) and also of the reaction of the intermediate in a Diels-Alder reaction (2) and the hydrogen reversion of the short-lived enol conformation (here: Z-conformation for R=H) to the starting molecule (3).

B) Photoisomerization of the long-lived conformation to the short-lived conformation.

C) Photoisomerization of the short-lived conformation to the long-lived conformation.

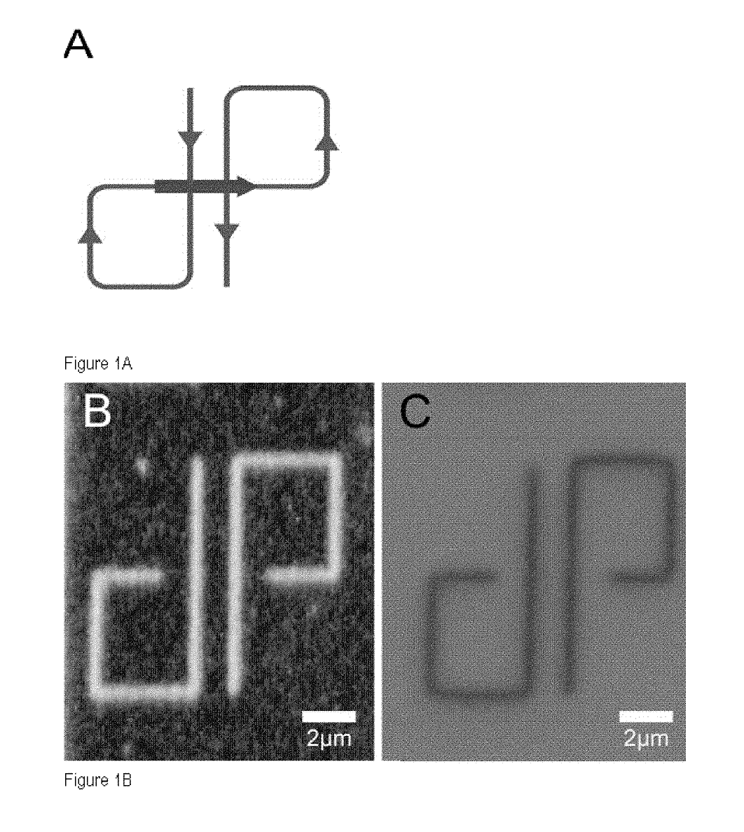

The photoenol chemistry used in the context of the present invention is switchable in its reactivity for lithographic procedures. One version involving the second wavelength likewise uses a Gaussian focus and no zero place. For technical reasons, one version employs as first wavelength not 350 nm, but 700 nm (femtosecond pulses), and the molecules are accordingly excited via two photon absorption. But this does nothing to change the photoenolization process. It was found that the molecules studied on being simultaneously irradiated with 440 nm light (second wavelength) do not trigger the expected chemical reaction even though they are sufficiently exposed to light of the first wavelength to form the reactive species. This behavior was specifically studied in two possible scenarios, namely a photoinduced surface functionalization and a photopolymerizable photoresist based on a photoenol. As a test, a path as indicated in FIG. 1A was exposed to light by moving the sample about. Corresponding results are shown in FIG. 1B for the surface functionalization and in FIG. 1C for the photoresist. The reaction is stopped by irradiation with the second laser. It is further apparent at the left-hand side crossing point that already exposed parts are not damaged by later renewed exposure to 440 nm light. It is apparent at the right hand side crossing point that the switching of the molecule is reversible with 440 nm light and that for this reason renewed exposure later at this point is possible.

One possible explanation for this switchability is that the enol formed, in the corresponding long-lived conformation, absorbs the light of the second wavelength and in the process transitions into the short-lived conformation (see B in the above scheme). Our results would be explained if the long-lived enol conformation transitions into the short-lived enol conformation on 440 nm irradiation and the opposite transition (short-lived to long-lived) is not triggered by this irradiation. Even if the two enol conformations have the same transient absorption spectrum and possibly even the short-lived enol can be photoinduced to transition into the long-lived enol (see C in the above scheme), however, the switching process is effective for resolution improvement because the lifetimes of the two enol species are very different. Since the short-lived conformation dies down faster by orders of magnitude with starting molecules being formed by mainly hydrogen reversion, irradiation at 440 nm would, by the constant exchange between short-lived and long-lived conformations, lead in the main to the long-lived enol conformation being depopulated and aligned in its lifetime with the short-lived conformation.

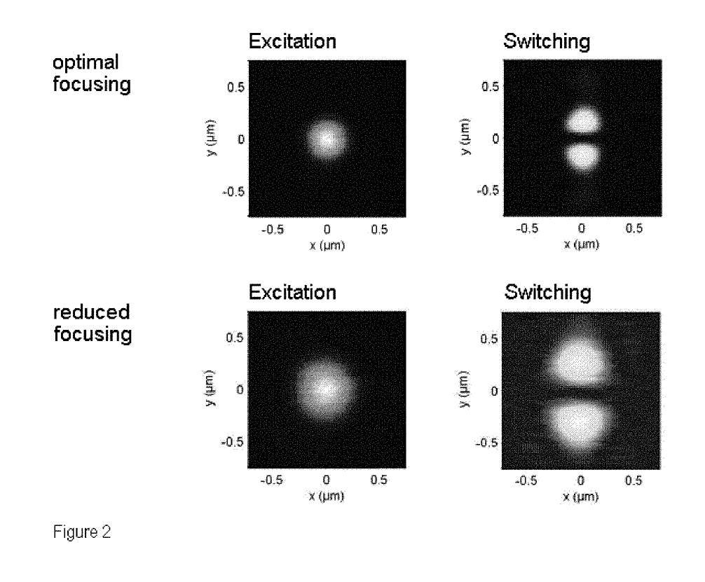

In addition to the in-principle reactivity switchability of the photoenol molecules, the present invention further provides for improved resolution. Switching here utilized a focus created by a so-called half moon phase plate (see FIG. 2). Such a setup improves the resolution only along one lateral direction, while the resolution in the other lateral direction remains unchanged. Points were exposed at certain intervals before checking whether the products are still spatially separate from each other after the photochemical reaction. As soon as the products were no longer spatially separate, the resolution limit of the optical-chemical system is reached.

It was found here that not only in the surface functionalization but also in the 3D lithography, the use of the second laser gave point spacings unattainable without the second laser.

The photoenol system was tested for the targeted functionalization of glass surfaces. To this end, the photoenol coated surface used was functionalized with biotin-maleimide (an efficient dienophile in Diels-Alder reactions) in a locationally resolved manner and then stained with streptavidin-Cy3. Then, fluorescence images of the surface were recorded with a microscope using structured illumination (SIM microscopy). An optical characterization of the result by fluorescence microscopy is simple and robust. Since, however, these procedures are themselves diffraction limited, they cannot be used to characterize very small distances. These experiments were therefore not carried out with the best possible focusing (in this case a fully illuminated microscope objective of numerical aperture NA=1.4, focus measurement see FIG. 2 above), but the focusing was first intentionally degraded by reduced beam diameter (focus measurement see FIG. 2 below). This corresponds to the situation of using an objective having a smaller NA. Even this situation is perfectly relevant for many applications, since it for example allows a larger working distance between the objective and the workpiece.

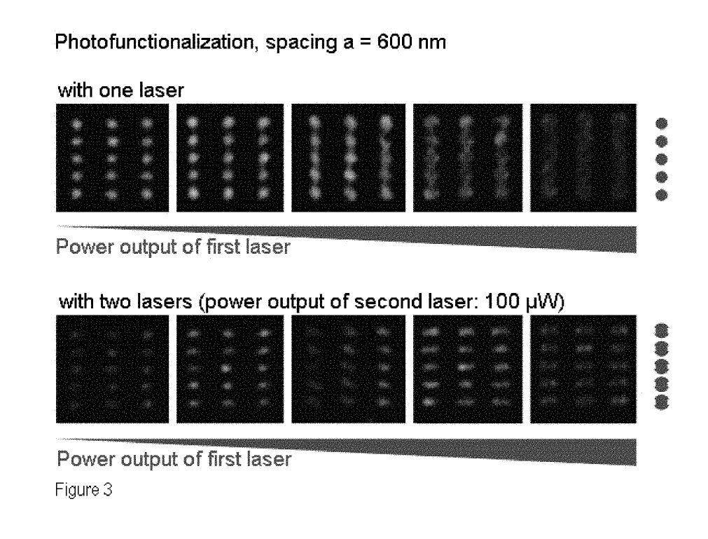

First, points were exposed at 600 nm distance (FIG. 3). In the conventional procedure (one laser only), the points are well separated for low exposure powers (at left). At increasing exposure power (from left to right), the pattern becomes increasingly fudged and the points are no longer clearly distinct. On using the second laser (constant power of 100 μW in all panels), the points are always clearly separated from each other. In addition, at large exposure powers (at right), a deformation of the effectively functionalized area becomes visible as would be expected from the chosen form of the switching focus: while the points become broader and broader in the horizontal direction, the width along the vertical direction scarcely increases by virtue of the improved resolution.

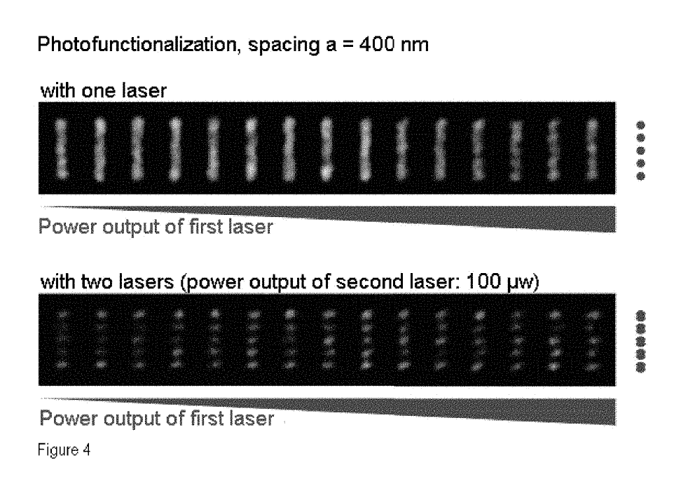

Subsequently a point spacing of 400 nm was tested (FIG. 4). A single laser did not give a satisfactory result: the laser power was varied across a wide range and cleanly distinct points were not found in any region. On using two lasers, cleanly separate points were found across a wide range of exposure powers. There is an unambiguous improvement in resolution.

To underscore the wide utility of the present invention, improved resolution was also shown in a photoenol system for photopolymerization. Again point exposures with various spacings were used. In each case, a small volume of a droplet of the liquid photoresist was polymerized close to the interface with a glass substrate. These oval points of polymer were bared by a wet chemical step of development and were subsequently examined under an electron microscope. Since the resolution of the electron microscope is very good, the optimal focusing was used for this experiment (FIG. 2 top).

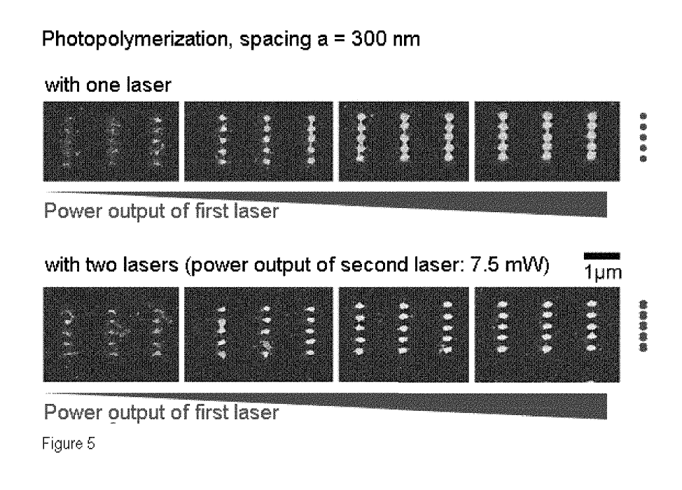

The power output of the excitation laser (first wavelength) was varied such that not only underexposed results (at left) but also overexposed results (at right) occurred. At a point spacing of 300 nm (FIG. 5) and only one laser, separate points are obtainable for certain ranges of power output (second panel from left). At somewhat higher power outputs, the points rapidly merge into a line. Together with the second laser, the result is distinctly better defined and acceptable over a wide range of excitation power outputs. Again, as in FIG. 3, it can be seen that for high excitation power outputs and on using two lasers (at right bottom), the points tend to become elliptical.

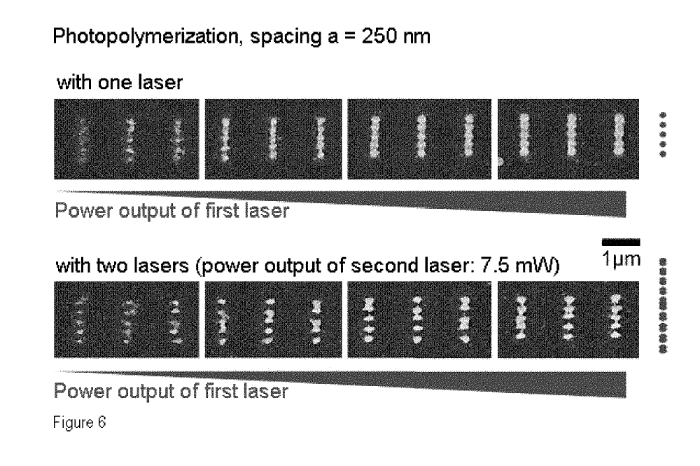

Using a point spacing of 250 nm (FIG. 6) and just one laser, points were found not to be separate but “merged” into a line, irrespective of the laser power output used. Again, the power output of the excitation laser (first wavelength) was varied so widely as to obtain a range from an underexposed result (at left) through to a clearly overexposed result (at right). In some cases, a slight thickness modulation of the resulting line is still visible. Together with the second laser, however, a better result is obtainable. The individual points are clearly visible and often quite distinct. Since the volume elements exposed are now fairly narrow in one direction by virtue of the improved resolution, and thus are more shaped like a disk than like a sphere, the individual points fall over sideways, which leads to the apparent variations in the period.

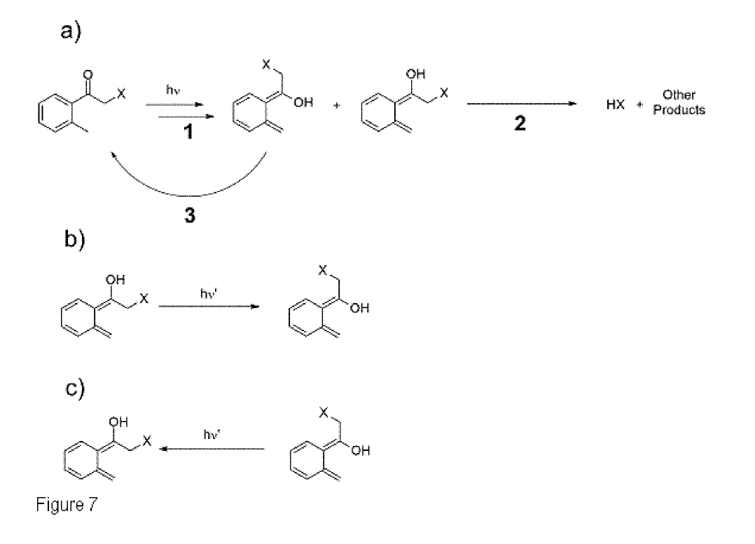

A further version of the invention provides for the release (photorelease) of a certain molecular species out of a photoenol molecule. A two color exposure is again able to restrict the region of release to spatial scales below the diffraction limit, as is not possible using the prior art. One example thereof is a release of HCl out of the molecule o-methylphenacyl chloride. FIG. 7 shows a term diagram for the reaction and also for the light-induced switching. The release of HCl proceeds from the reactive intermediate. Conformation switching of the photoenol serves to shorten the lifetime of the enol and effectively reduce the release rate. This release method is not limited to HCl. Further suitable possibilities for release include, for example, further halohydric acids (HBr, Hl, HF), amines, alcohols, carboxylic acids, phosphates and sulfonic acids. The released substances may find a wide variety of applications. In lithography, for example, photoacids are used to polymerize photoresists (cationic polymerization) or to increase the solubility of lacquers (in positive lacquers for example). Similarly in deep UV lithography, photoacid generators (PAGs) are used. In this way this spatially restricted release can again be used for photolithography with a resolution below the diffraction limit. Further applications are found in cell biological research, where substances are precisely releasable in parts of a cell. Also encompassed here are all further chemical reactions for which the molecules created by photorelease are suitable (such as, for example, a nucleophilic substitution of photoreleased amines and alcohols).

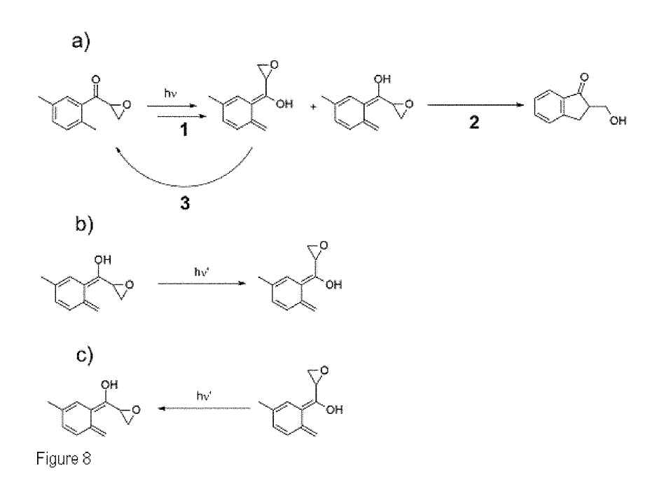

A further version of the invention provides for certain intramolecular groups being uncaged (photouncaged) by use of photoenol chemistry. This functionality is initially not present or inactive (for sterical reasons for example) and is first intramolecularly created or activated by a photochemical reaction. For instance, the intramolecular reaction of the created reactive species with an epoxide can be used to create an aliphatic alcohol. Since the reaction described proceeds via the above-described reactive species (o-quinodimethane), the reaction can likewise be used to inhibit a light-induced deactivation of this species. By use of two colors, it is again possible to massively reduce the spatial extent of the reaction volume. FIG. 8 shows an exemplary reaction scheme for such an uncaging reaction and also for the light-induced switching.

Lithography applications come into consideration again for example. There the uncaged groups may for example catalyze a reaction for solubility modification, or the groups created may constitute the attack points for an etch in order to destabilize a polymer network. Further possibilities are again all chemical reactions for which the groups created or activated by photouncaging are suitable (nucleophilic substitution for example).

The present invention provides a way to virtually circumvent the optical diffraction limit. For instance, a spatially closer confined excitation can be optically introduced into a photoresist layer than would be possible with a conventional optical exposure, and thus produce smaller structures.

Not only one but also multiple photon absorption can be used for excitation. The spatial confinement of the excitation is independent of the excitation mode.

The method of optical lithography below the diffraction limit as per the present invention comprises the steps of:
a) a lacquer containing or consisting of
   (i) at least one photoenol,
   (ii) at least one dienophile,
   (iii) optionally a solvent or solvent mixture,
   (iv) optionally further auxiliary substances, being applied to a substrate
b) the polymerization being initiated at a selected site by irradiation with light, preferably a laser, of a first, photoenol-activating, wavelength, and concurrently or thereafter
c) the polymerization being suppressed in the immediate vicinity of the selected site by irradiation with light, preferably a laser, of a second, photoenol-deactivating wavelength,
   wherein
   the deactivation light radiated creates an interference pattern having an intensity minimum or zero intensity at the selected site.

One version of the present invention is a method of optical lithography below the diffraction limit comprising
a) providing an optical molding on the basis of a photoenol-dienophile system,
b) the polymerization being initiated at a selected site by irradiation with light, preferably a laser, of a first, photoenol-activating wavelength, and concurrently or thereafter
c) the polymerization being suppressed in the immediate vicinity of the selected site by irradiation with light, preferably a laser, of a second, photoenol-deactivating wavelength,
   wherein
   the deexcitation light radiated creates an interference pattern having an intensity minimum or zero intensity at the selected site.

The present invention utilizes a photoenol which is deactivatable by irradiation with a second wavelength before it starts the chemical reaction. A further chemical reaction is locally inhibited as a result.

A deexcitation light in addition to the excitation creates an interference pattern which has an intensity minimum or ideally zero intensity in those places where very small structures are to be created. The effect of the optically introduced excitation is thus locally reduced according to the deexcitation intensity, substantially at high intensities, minimally at small ones and not at all at zero intensity. In consequence, multiplying of the entire excitation power output may provide an ever greater narrowing of the remaining excitation about the local minimum.

This apparatus-based approach corresponds to the methods described in DE 10 2010 000 169.

In the present invention, it is preferably laser light which is used to create not only excitation but also deexcitation.

The useful photoenols for the purposes of the present invention enable the production in a photoresist or holographic storage medium, together with the use of an additional laser for de-excitation, of smaller structures than is possible with conventional optical lithographic techniques at comparable wavelengths and apertures.

In the method of the present invention, the additional (laser) light is used to create about the place to be exposed an interference pattern which at this place has an intensity minimum (ideally of intensity zero). In the exposure operation with the first light source, the photoenol is then deactivated according to the local intensity of the additional light source. The de-excitation is at its weakest in the intensity minimum, and absent in the case of zero intensity. The remaining excitation, which ultimately leads to a chemical reaction, for example polymerization, can in principle be restricted further and further by increasing the power output of the second laser.

The present invention enables the structure size to be established independently of the crosslink density, making it possible for example to produce very small and simultaneously stable structures.

A useful photoresist for the purposes of the present invention may consist of the constituents described above, subject to the proviso that it has to contain at least one of the abovementioned photoenols and at least one dienophile. It may contain solvent and be usable not only in solid form but also in liquid form, and in one version is oxygen insensitive.

One example of a useful photoresist for the purposes of the present invention is based on a polymer having a multiplicity of functional dienophilic groups, for example maleimide groups, in pending form, a photoenol, for example 6,6′-((2,2-bis((2-formyl-3-methylphenoxy)-methyl)propane-1,3-diyl)bis(oxy))bis(2-methyl-benzaldehyde), and one or more solvents, for example a mixture of GBL and acetophenone.

In one version of the present invention, the lacquer does not include any solvent.

In one version of the present invention, the excitation laser has a central wavelength between 250 nm and 450 nm, preferably between 300 nm and 400 nm, more preferably between 320 nm and 350 nm and yet more preferably 350 nm.

In one version of the present invention, the excitation laser has a central wavelength between 500 nm and 800 nm, preferably between 600 nm and 700 nm, more preferably between 640 nm and 700 nm and yet more preferably 700 nm. Pulsed lasers are usable here with preference.

In one version of the present invention, the de-excitation laser has a central wavelength between 400 nm and 600 nm, preferably between 420 nm and 480 nm, more preferably between 430 nm and 450 nm and yet more preferably 440 nm.

The excitation laser used in one version of the present invention is a continuous wave laser with 351 nm central wavelength.

The excitation laser used in one version of the present invention is a laser with 150 femtoseconds pulse duration, 80 MHz repeat rate, 700 nm central wavelength.

The de-excitation laser used in one version of the present invention is a continuous wave laser (cw) having a central wavelength of 440 nm central wavelength.

The excitation and de-excitation lasers may each independently be either both pulsed, both continuous or one pulsed and the other continuous in operation.

One version of the present invention comprises radiating the excitation light in pulsed operation and the de-excitation light in pulsed or continuous wave (cw), preferably continuous wave, operation.

The method of the present invention requires no additional ingredients, but utilizes an inherent property of the photoenol. In the case of the present invention, the system of photoenol and dienophile, the lacquer system for example, only absorbs the de-excitation light where there is also some excitation. As a result, the de-excitation light can be focused deeply into a sample. It is thereby possible, together with a multiple photon excitation, to produce three-dimensional structures, especially with improved resolution.

The method of the present invention is therefore employable not only to two-dimensional lithography but also to three-dimensional lithography.

The use of the photo-deactivatable photoenols referred to has the advantage that they absorb in the UV region, preferably at 300-450 nm, so common methods of UV exposure can be employed. The processing of the samples can be carried out under yellow light or red light.

The resulting structures out of the method according to the present invention can be engineered to be transparent in the visible spectrum and therefore employed for the production of nano- and microoptical devices.

The present invention enables inter alia a sequential punctuate exposure to focused light and single or two photon absorption. It is similarly possible for example to use traditional single photon absorption for large area parallel lithography as well. To this end, instead of a single doughnut-shaped focus, it is then for example an intensity lattice created by interference and its null positions which are used. Excitation may utilize a large area pattern of light, created either statically (with a mask for example) or dynamically (for example by means of a liquid crystal spatial light modulator) or an MEMS digital mirror device.

Similarly with data storage devices based on using laser light to crosslink in an optical molding, i.e., in a polymer matrix, small points more strongly to thereby change their refractive index, the present invention is capable of achieving smaller points and thus higher data densities.

In one version of the present invention, the laser beams for initiation (excitation) and deactivation (de-excitation) are combined with a beam divider and focused together by a microscope objective through a cover slip into a droplet of the photoresist. Since a phase mask is used in the deactivation beam ahead of the beam divider, this beam creates, in the focus of the objective, a doughnut shaped interference pattern having a deep minimum in the center. The beams are oriented such that the focus of the excitation laser is centered precisely about this minimum. It is thereby possible to polymerize individual three-dimensionally confined points in the focus. By shifting the sample relative to the focus, any desired structures are obtainable by serial punctuate exposures.

The additional introduction of the de-excitation laser inhibits the chemical reaction in the periphery of the otherwise diffraction limited reaction volume and thereby reduces the dimensions of the smallest obtainable volume element.

In one version of the present invention, the excitation and de-excitation lasers are focused separately from each other. The present invention makes it possible for example to have one beam pass from above into the lacquer or molding while the other beam passes from below or at an angle from above into the lacquer or molding. What is essential is that the beams meet in the focus point.

Lateral entry of the beams into the sample is also conceivable.

It is self-evidently not necessary to focus through a cover slip into a droplet of a lacquer. It is merely necessary that the lacquer be placed in a distance in front of the microscope objective that focusing into it is possible. It is similarly possible to provide not droplets but larger amounts of lacquer for treatment. It is then merely more physically cumbersome to move/position the lacquer, but larger structures can then be created. These versions are encompassed by the present invention.

In one version of the present invention, it is not a conventional excitation which is carried out at 350 nm but a two photon excitation with femtosecond laser pulses having a central wavelength of 700 nm.

One version of the present invention utilizes a conventional excitation with UV light at 350 nm.

It was found in the context of the present invention that, for the same excitation power output and translation speed, the additional use of the de-excitation laser with or without a phase mask made it possible to achieve an appreciable reduction in line width.

The present invention lastly also provides a lithographic lacquer for methods of optical lithography below the diffraction limit, containing or consisting of

(i) one or more photoenols, and
(ii) one or more dienophiles,
(iii) optionally the abovementioned solvents.

In one version of the present invention, the lithographic lacquer consists of

(i) one or more photoenols, and
(ii) one or more dienophiles.

It is an immense advantage of the present invention that the hitherto unknown photo-deactivatability of a known photoenol is exploited in order to be able to produce smaller structures.

The present invention makes it possible to produce spatially smaller structures by optical means than this was hitherto possible with corresponding chemical systems.

The invention is of great interest in the entire field of the optical-lithographic production of small and very small structures. It can likewise be used for the development of optical data storage media having extremely high data density.

The present invention is used inter alia for photoresist systems for extremely highly resolving lithography, for and/or in the semiconductor industry in general, for fast prototyping for microchips, and also in the manufacture of optical component part elements.

The present invention is useful not only for the production of small planar or three-dimensional structures but also for writing optical data storage media of high density, since similar crosslinking reactions can be used there, and the diffraction limit can be circumvented in a similar way.

The present invention also provides the method of using photoenols, preferably ortho-alkylbenzaldehydes and -ketones for conducting and/or initiating photochemical reactions, preferably for optical lithography, especially in lacquers for optical lithography, below the diffraction limit by use of light having two wavelengths, for functionalization of surfaces, especially glass surfaces.

The present invention further provides a method for structured functionalization of surfaces, especially glass surfaces, which comprises
a) (i) at least one photoenol, and/or
   (ii) at least one dienophile,
   (iii) optionally a solvent or solvent mixture,
   (iv) optionally further auxiliary substances being applied to and fixed on a substrate,
b) the reaction of photoenol and dienophile(s) being initiated at a selected site by irradiation with light, preferably a laser, of a first, photoenol-activating wavelength (excitation light), and concurrently or thereafter
c) the reaction of photoenol and dienophile(s) being suppressed in the immediate vicinity of the selected site by irradiation with light, preferably a laser, of a second, photoenol-deactivating wavelength (de-excitation light),
   wherein
   the de-excitation light radiated creates an interference pattern having an intensity minimum or zero intensity at the selected site,
   and the structuring is created by methods of radiated light.

Fixing the photoenol and/or the dienophile in this context may be effected for example as a result of the particular surface being occupied by or consisting of a polymer and the photoenol and/or dienophile being attached to this polymer as a functional group. The photoenol and/or dienophile may similarly be attached as functional groups to existing functional groups on the surface, in that for example they may be attached to a glass surface via OH groups present thereon.

The present invention further provides the method of reducing the lithographic scale and/or the lithographic resolution in optical lithography by use of photoenols, preferably ortho-alkylbenzaldehydes and -ketones.

The photochemical reactions and/or polymerizations of the present invention proceed not via a free radical reaction mechanism, but via photoinduced Diels-Alder reactions.

The present invention can be used to establish lithographically created structures on orders of magnitude, stated in the order of preference, down to 600 nm, 500 nm, 40 nm, 350 nm, 300 nm, 275 nm, 250 nm, 225 nm, 200 nm, 175 nm, 150 nm, 140 nm, 130 nm, 120 nm, 110 nm, 100 nm, 90 nm, 80 nm, 70 nm, 60 nm, 50 nm, 40 nm, 30 nm, 20 nm, 10 nm, 5 nm.

A particularly preferred version of the present invention is a method of optical lithography below the diffraction limit wherein
a) a lacquer consisting of
   (i) at least one photoenol selected from the group consisting,
   (ii) at least one dienophile selected from the group consisting of,
   is applied to a substrate,
b) the reaction is initiated at a selected site by irradiation with light, preferably a laser, of a first, photoenol-activating wavelength (excitation light) between 250 and 400 nm, preferably between 300 and 350 nm, more preferably between 320 and 350 nm, especially 350 nm or between 500 and 800 nm, preferably between 600 and 700 nm, more preferably between 640 and 700 nm and especially 700 nm, and concurrently or thereafter, preferably concurrently
c) the reaction is suppressed in the immediate vicinity of the selected light by irradiation with light, preferably a laser, of a second, photoenol-deactivating wavelength (de-excitation light) between 400 and 500 nm, preferably between 420 and 480 nm, more preferably between 430 and 450 nm and especially 440 nm,
   wherein
   the de-excitation light radiated creates an interference pattern having an intensity minimum or zero intensity at the selected site.

A most highly preferred version here is that combining the most highly preferred versions in each case.

Advantages of the present invention are the universal utility and also the mild conditions of the photoenol chemistry used. The present invention further makes possible a large bandwidth of covalent functionalizations below the diffraction limit, since the o-quinodimethane intermediate formed may be utilized inter alia as a reactive diene for Diels-Alder reactions (click reactions). It is thereby readily possible to use a multiplicity of different molecules as reaction partners. One important feature of the invention is therefore the coupling of a switchable system (photoenolization) with a widely usable intermediate (diene for Diels-Alder reactions). A further massive advantage is the possibility of parallelization, i.e., the concurrent practice of a lithographic process on a large area, by virtue of the low power outputs required. This makes for an enormous increase in throughput.

The present invention has a further advantage in its good utility in photorelease and/or photouncaging processes.

The present invention makes possible the use of a broad spectrum of photoreactions/reaction partners under mild conditions and not just a photoinduced free radical polymerization reaction.

Compared with the already very good systems of DE 10 2010 000 169, one advantage of the present invention is that the photoenol can be switched at significantly lower power outputs (about 100 μW) and therefore is suitable for appreciably larger throughput by parallelization than the photoinitiator system of DE 10 2010 000 169, where the light power outputs required for the second wavelength amount to about 50 mW.

The present invention is further advantageous over the likewise highly resolving technique of RESOLFT microscopy, since with the latter it is neither possible to create an etched contrast (as would be necessary for any use in the semiconductor industry) nor to dock some other molecular species onto the molecules. Nor does it allow for photorelease or photo-uncaging. So the chemical reaction which is optically induced is unspecific and not further useful, whereas the photoenol reaction of the present invention is universally useful and inter alia, by virtue of its high efficiency under mild conditions, employable as a click reaction. The strict criteria underlying a click reaction therefore enable/facilitate the integration of the present invention into a multiplicity of applications.

The present invention also exhibits advantages over absorption modulation lithography. In absorption modulation lithography, a layer is placed between the light source and the photosensitive substance (sensitive at wavelength one) and the transmission behavior of said layer is alterable with a second wavelength. The second wavelength may be used for instance to create an opaque layer which is solely transparent in a very small point. As a result, only a very small region would transmit the light of wavelength one in order to expose the light-sensitive substance therebehind and to start the photoreaction. Owing to the diffraction effects of light at this small opening, however, the transmitted beam would very quickly broaden out again with increasing distance from the layer. A photoreaction can therefore then only be started in the form of very thin layers and with two-dimensional structurization. Using the photoenol approach of the present invention, however, the reaction can also be limited in three dimensions and is not confined to thin layers. In addition, the absorbance of photochromic layers in absorption modulation lithography is generally not very high, so the attainable resolution is limited by a diffusely transmitted background of wavelength one.

It was the efficient switchability which, in the context of the present invention, was achieved by photoisomerization in the systems of the present invention. The systems of the present invention make it possible for the entire reaction path of the intermediary species to be altered, and returned losslessly to the starting molecule, by suitable irradiation, despite reactive intermediates and high intensities during the pulses. This enables inter alia an extremely effective utilization of the amounts of substances used.

Another surprise is the high yield which is achieved within a very short time by the isomerization referred to and makes a lithographic application possible in the first place, since reactive partners of the long-lived ortho-quinodimethane species are at the ready and the reaction which is suppressed here is a conventional click reaction, which is known for its high reaction rate and yield. The present invention thus surprisingly enables an enhanced controllability over reactions such as click reactions.

The various embodiments of the present invention, for example—but not exclusively—those of the various dependent claims, are combinable with each other in any desired manner.

FIG. 1A and FIG. 1B show test patterns to demonstrate the reversible switchability of photoenol chemistry.

FIG. 1A shows under A) a schematic depiction of the exposure path of the first laser (red). The superposed second laser (blue) is additionally activated in the central segment.

FIG. 1B shows under B) a fluorescent picture (photograph) of the resulting pattern from the functionalization of a photoenol coated glass surface with biotin-maleimide and subsequent staining with streptavidin-Cy3. In the central part, the photofunctionalization is suppressed by the second laser. FIG. 1B further shows under C) an optical micrograph in reflection of the resulting pattern from a photo-polymerization near a glass surface. Again, in the central part, the photopolymerization is suppressed by the second laser.

FIG. 2 shows focus measurements of the excitation laser (first wavelength=700 nm, at left) and of the switching laser (second wavelength=440 nm, at right). The zero place/zero line of the switching laser is responsible for the enhanced resolution. In this case, the reaction volume is thereby restricted in the y-direction (resolution improvement) whereas it remains unchanged in the x-direction. To carry out the measurement, a 100 nm particle of gold was moved through the focus and the backscattered light was measured and recorded.

FIG. 3 shows fluorescence images of a resolution test from the photofunctionalization of a photoenol-coated glass surface with biotin-maleimide and subsequent staining with streptavidin-Cy3. The exposure process is schematically indicated at right with the various forms of focus. The power output of the first laser is gradually increased from left to right.

FIG. 4 shows fluorescence images of a resolution test from the photofunctionalization of a photoenol-coated glass surface with biotin-maleimide and subsequent staining with streptavidin-Cy3. The exposure process is schematically indicated at right with the various forms of focus.

FIG. 5 shows scanning electron micrographs of a resolution test from the photopolymerization in the vicinity of a glass surface. The exposure process is schematically indicated at right with the various forms of focus. To improve the adherence, the glass surface had been additionally photoenol coated.

FIG. 6 shows scanning electron micrographs of a resolution test from the photopolymerization in the vicinity of a glass surface. The exposure process is schematically indicated at right with the various forms of focus. To improve the adherence, the glass surface had been additionally photoenol coated.

FIG. 7 shows the reaction scheme for an exemplary photorelease reaction resulting in the release of HCl (A). Also shown is the light-induced switching process for deactivating the reactive intermediate (B), and also a possible contrary isomerization (C).

FIG. 8 shows the reaction scheme for an exemplary photouncaging reaction (A). Also shown is the light-induced switching process for deactivating the reactive intermediate (B), and also a possible contrary isomerization (C).

In the examples of the present invention, a 700 nm laser of 150 fs pulse length and 80 MHz repetition rate was focused with an oil immersion objective (Leica HCX PL APO 0.7-1.4 OIL CS) into the particular sample through a cover lid. In addition, the same objective was used to focus a 440 nm continuous wave laser, selectively in a spatial mode having a zero place (see FIG. 2). The laser power outputs were adapted with acousto-optical modulators. While the laser foci were spatially fixed, the sample was moved with piezo tables to an accuracy of a few nanometers. The desired structures were thus created from sequential point exposures.

This is a preferred procedure in one version of the present invention.

1.-16. (canceled)

17. A method of conducting a photochemical reaction below the diffraction limit, wherein the method comprises
(a) providing a composition comprising or consisting of
(i) at least one photoenol,
(ii) optionally, at least one reaction partner,
(iii) optionally, a solvent or solvent mixture,
(iv) optionally, further auxiliary substances,
(b) initiating a reaction which emanates from the at least one photoenol at a selected site by irradiation with light of a first, photoenol-activating wavelength, and concurrently or thereafter
(c) suppressing the reaction emanating from the at least one photoenol in an immediate vicinity of the selected site by irradiation with light of a second, photoenol-deactivating wavelength,
the photoenol-deactivating light creating an interference pattern having an intensity minimum or zero intensity at the selected site.

18. The method of claim 17, wherein the light of the first wavelength and/or the light of the second wavelength is emitted by a laser.

19. The method of claim 17, wherein the method is effected via photorelease, photouncaging or a combination thereof.

20. The method of claim 17, wherein
(a) an optical molding or a lacquer comprising or consisting of
(i) at least one photoenol,
(ii) at least one dienophile,
(iii) optionally, a solvent or solvent mixture,
(iv) optionally, further auxiliary substances,
is applied to a substrate,
(b) a reaction of the at least one photoenol and the at least one dienophile is initiated at a selected site by irradiation with light of a first, photoenol-activating wavelength (excitation light), and concurrently or thereafter
(c) the reaction of the at least one photoenol and the at least one dienophile is suppressed in an immediate vicinity of the selected site by irradiation with light of a second, photoenol-deactivating wavelength (de-excitation light),
the de-excitation light creating an interference pattern having an intensity minimum or zero intensity at the selected site.

21. The method of claim 20, wherein the light of the first wavelength and/or the light of the second wavelength is emitted by a laser.

22. The method of claim 17, wherein the at least one photoenol comprises a photoenol of the following formula: 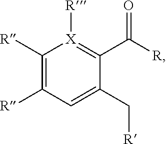
wherein:
R=H, alkyl, preferably methyl, aryl, halogenated alkyl,
R′=H, alkyl,
R″=H, alkyl, alkoxy, alkoxy wherein an alkyl moiety bears at least one functional group,
R′″=H, hydroxyl, alkyl, alkoxy, alkoxy wherein an alkyl moiety bears at least one functional group,
X=C, N,
with the proviso that when X=N, R′″ is absent.

23. The method of claim 22, wherein the at least one photoenol comprises an ortho-alkylbenzaldehyde or -ketone.

24. The method of claim 17, wherein a deactivation laser has a wavelength of from 400 to 600 nm and/or an excitation laser is a continuous wave (cw) laser.

25. The method of claim 24, wherein the excitation laser is a continuous wave (cw) laser having a central wavelength of 351 nm.

26. The method of claim 20, wherein the at least one dienophile comprises at least one of dienophile selected from maleimides, maleic anhydride, maleic di- and monoesters, fumaric di- and monoesters, alkynes, acrylates, methacrylates, dithioesters, trithiocarbonates, propenals, butenals, fullerenes, dicyanoethene, tetracyanoethene, acetylenedicarboxylic mono- and diesters, but-2-en-4-olides, and derivatives thereof.

27. The method of claim 26, wherein the at least one dienophile comprises maleimide.

28. The method of claim 17, wherein (iv) comprises one or more auxiliary substances selected from surface-active substances, flow control agents, pigments, fillers, crosslinkers, stabilizers, and photoprotectants.

29. The method of claim 20, wherein the optical molding or the lacquer consists of (i) and (ii).

30. A method for structured functionalization of a surface, wherein the method comprises
(a) applying to and fixing on a substrate
(i) at least one photoenol, and/or
(ii) at least one dienophile,
(iii) optionally, a solvent or solvent mixture,
(iv) optionally, further auxiliary substances
(b) initiating a reaction of the at least one photoenol and/or the at least one dienophile at a selected site by irradiation with light of a first, photoenol-activating wavelength (excitation light), and concurrently or thereafter
(c) suppressing the reaction of the at least one photoenol and/or the at least on dienophile in an immediate vicinity of the selected site by irradiation with light of a second, photoenol-deactivating wavelength (de-excitation light),
the de-excitation light creating an interference pattern having an intensity minimum or zero intensity at the selected site, and the structuring being created by a method of radiated light.

31. The method of claim 30, wherein the light of the first wavelength and/or the light of the second wavelength is emitted by a laser.

32. A method of conducting and/or initiating a photochemical reaction below the diffraction limit by using light having two wavelengths for functionalization of a surface, wherein the method comprises employing at least one photoenol for conducting and/or initiating the photochemical reaction.

33. The method of claim 32, wherein a lithography is created down to 600 nm.

34. A method of conducting a photochemical reaction below the diffraction limit, wherein the method comprises
(a) providing an optical molding,
(b) initiating a reaction of at least one photoenol and at least one dienophile at a selected site by irradiation with light of a first, photoenol-activating wavelength, and concurrently or thereafter
(c) suppressing the reaction of the at least one photoenol and the at least one dienophile in an immediate vicinity of the selected site by irradiation with light of a second, photoenol-deactivating wavelength,
the light of the second wavelength creating an interference pattern having an intensity minimum or zero intensity at the selected site.

35. The method of claim 34, wherein the light of the first wavelength and/or the light of the second wavelength is emitted by a laser.

36. A lithographic lacquer, wherein the lacquer comprises or consists of
(i) one or more photoenols, and
(ii) one or more dienophiles,
and is suitable for conducting the method of claim 20.
